(19) United States
(12) Patent Application Publication
(10) Pub. No.: US 2009/0251152 A1
(43) Pub. Date: Oct. 8, 2009

(54) METHOD AND DEVICE FOR MONITORING AND/OR DETERMINING THE CONDITION OF A MEASURING PROBE

(75) Inventor: Jurgen Ammann, Zurich (CH)

Correspondence Address: STANDLEY LAW GROUP LLP, 6300 Riverside Drive, Dublin, OH, 43017, US

(73) Assignee: Mettler-Toledo AG, Greifensee (CH)

(21) Appl. No.: 12/486,994

(22) Filed: Jun. 18, 2009

Related U.S. Application Data
(63) Continuation of application No. PCT/EP2007/064170, filed on Dec. 19, 2007.

(30) Foreign Application Priority Data
Dec. 22, 2006 (EP) 06127183.9

(51) Int. Cl. G01N 27/62; G01R 31/02

(52) U.S. Cl. 324/459; 324/537

(57) ABSTRACT

The condition of an electrochemical measuring probe (1) such as for example a pH-measuring probe, an oxygen-measuring probe, or a CO₂-measuring probe is monitored and/or controlled. The measuring probe (1) has at least one electrode (EL) and is suitable for measuring the ion concentration of a process material (6). A charge storage device (Q2) which belongs to the electrode is charged up during a charge-up phase (T_{L}) by means of a charge transfer that can be controlled by a controller unit (CU). During a subsequent test phase (T_{T}) the resultant electrode voltage (U_{E}) is measured at least once, and the result of the measurement is processed further.

### CROSS-REFERENCE TO RELATED APPLICATIONS

This application is a continuation of PCT/EP2007/064170, filed 19 Dec. 2007, which designates the United States, and which, in turn, claims a right of priority under 35 USC §119 from European patent application 06 12 7183.9, filed 22 Dec. 2006. The content of each of these is incorporated by reference as if fully recited herein.

### TECHNICAL FIELD

The present disclosure relates to a measurement method and a measuring device for monitoring and/or for determining the condition of an electrochemical measuring probe such as for example an ion-sensitive measuring probe, in particular a pH-measuring probe, an oxygen-measuring probe, or a CO₂-measuring probe.

### BACKGROUND OF THE ART

The monitoring and control of industrial processes, for example in the chemical and pharmaceutical industries, in the textile industry, in the food and beverage industries, in the processing of paper and cellulose, or in the fields of water processing and waste water treatment, is based on the measurement of process variables that are determined by means of suitable measuring probes.

According to “Process Measurement Solutions Catalog 2005/06”, Mettler-Toledo GmbH, CH-8902 Urdorf, Switzerland, pages 8 and 9, a complete measuring system consists of a housing, a measuring probe, a cable and a measurement converter (also called a transmitter). By means of the housing, the measuring probe is brought into contact with the process that is to be measured or monitored, for example by immersing the probe in the process material and holding it there. The measuring probe serves to measure specific properties of the process. Measurement signals are sent through the cable to the transmitter which communicates with a process control system and converts the measuring signals into readable data. The measuring probes are selected depending on the process material properties that are to be measured.

Another Mettler-Toledo GmbH company publication, “Process-Analytical Systems Solutions for the Brewery”, Article No. 52 900 309, published in Switzerland with a printing date of September 2003, describes how suitable measuring probes are used for example in individual stages of the process chain of a brewery (i.e., in the water processing stage; the brew house; the fermentation and storage cellar; the filtration-, carbonization- and filling stages; as well as the waste water treatment stage) to determine the conductivity, the amount of dissolved oxygen, the pH value, and the CO₂ value of the process liquid.

For the problem-free control of a process, the condition of the measuring probes is of critical importance. Erroneous measurements can lead to production defects and losses with corresponding financial consequences.

Typically, an electrochemical measuring probe such as for example a pH-measuring probe or an oxygen-measuring probe is subject to a load-dependent wear process which is inherent in the functional principle of the probe and which normally leads to a continuous change of the measurement characteristics of the measuring probe.

Such changes call for appropriate action in the form of maintenance operations at more or less regular intervals. This may require for example a cleaning, an exchange, a recalibration of the measuring probe or an error compensation, a special rating or a correction of the measurement values.

The present state of the art offers a variety of diagnostic procedures to determine the state of wear of a measuring probe. For example in JP 57-199950, a method is described where the measuring probe is immersed in a liquid of prescribed concentration, a so-called calibration liquid. Next, the electrode is connected to a charged capacitor, and the discharge speed of the capacitor is determined. As the charge which is affecting the electrode always has the same polarity, a unipolar charge influx is taking place. This diagnostic procedure, which is also referred to as off-line method, has the disadvantage that the primary measurement function, i.e. the determination of the ion concentration of the process material, needs to be interrupted for an extended time period in order to bring the measuring probe into contact with the calibration liquid.

According to German laid-open application DE 10209318, in the case of a pH-measuring probe, the preferred parameters from which the state of wear of the measuring electrode can reliably be determined are the zero point, the slope, and the impedance or the settling time of the electrode. However, the measurement methods associated with these parameters have the disadvantage that they can only be performed during a break in the process, i.e. typically during a calibration of the process system.

Particularly in industrial process systems where a large number of measuring probes is being used, these off-line diagnostic procedures generate costly maintenance operations, and in particular the planning of the maintenance intervals entails a high logistics effort. As a result, there is a growing demand for so-called in-line diagnostic methods which allow the condition of a measuring probe to be determined and/or monitored without interrupting the process that is to be monitored. Especially the steps of uninstalling the measuring probe from the process system and removing the measuring probe from the process material should be avoided.

The known state of the art offers diagnostic methods that are based on the principle of resistance measurement and which allow damages and malfunctions of a measuring probe to be determined through continuous monitoring without interrupting the process.

In an example according to U.S. Pat. No. 4,189,367, the condition of a glass electrode which is used in pH measurements is monitored through a continuous resistance measurement in order to detect when the glass membrane is damaged. Under this concept, a first test current is sent through the electrodes by means of a controlled switching device and the change of the resultant voltage is measured. If the change of the electrode voltage does not match an expected value, this is an indication of a defective electrode. Following the measurement, a second test current of opposite direction but equal magnitude and duration as the first test current is sent through the electrode. With this second test current, the effect of the first test current on the electrode is essentially canceled. Accordingly, a bipolar excitation is taking place which returns the measuring probe into the operating condition for measuring the ion concentration of the process material.

This in-line diagnostic method has the disadvantage that it requires the use of expensive switching devices which need to have a very high insulation resistance. As shown in WO 92/21962 or in U.S. Pat. No. 4,468,608, the test currents of opposite direction can also be generated by means of a square-shaped voltage pulse which is introduced by way of a coupling capacitor. According to U. Tietze, Ch. Schenk, “Halbleiter-schaltungstechnik” (Semiconductor Circuit Design), 12^{th} edition, published by Springer Verlag, Berlin 2002, page 1538, the measuring probe and the coupling capacitor are acting in this case as a coupling RC member and thereby cause a differentiation of the square wave signal.

With the differentiation of the rectangular voltage pulse, the first pulse flank is converted into a first test current, and the second pulse flank is converted into a second test current flowing in the opposite direction of the first test current. Accordingly, the electrode is likewise subjected to a bipolar signal.

The state-of-the-art in-line diagnostic methods are suitable for the continuous measurement and thus for the continuous monitoring and for the detection of impairments and malfunctions of an electrode such as are caused by breakage of the ion-sensitive membrane, contamination of the diaphragm, a circuit interruption in a conductor lead, or a short circuit. However, they allow only an unsatisfactory diagnosis of the general condition and particularly of the current state of wear of a measuring probe.

There is an objective to provide an improved method and an improved device for monitoring and/or for determining the condition of an electrochemical measuring probe, specifically a pH-measuring probe, an oxygen-measuring probe, or a CO₂-measuring probe, wherein the measuring probe has at least one electrode, and wherein during operation of the measuring probe a measurement quantity can be determined which is related to the ion concentration of a process material.

### SUMMARY

This objective is met by a method and a device with the features stated in the independent claims respectively. Additional advantageous embodiments are presented in further claims.

Under the method for monitoring and/or for determining the condition of an electrochemical measuring probe, specifically of a pH-measuring probe, an oxygen measuring probe or a CO₂-measuring probe, by means of which the ion concentration of a process material can be determined, at least one verification phase is arranged to take place during operation (in-line). This verification phase includes a charge-up phase that is followed immediately by a test phase. During the charge-up phase a charge storage device which is assigned to the electrode, specifically a capacitor, is charged up by means of a charge transfer under the control of a controller unit, or an already charged charge storage device is switched into the electrode circuit, and at the start of the test phase the charge storage device is disconnected by means of a first switching device from a charge source or, if applicable, from a supply voltage, and the electrode voltage that results from the charge is measured at least once during the test phase, whereupon the one or more measurement values that were acquired are compared to at least one reference value. As the charge source is being isolated by disconnecting the charge storage device from the charge source, the second test current which flows in the opposite direction is blocked. Accordingly, the electrode receives in essence a unipolar signal. This allows important additional information to be gained about the condition of the measuring probe, for example about the mobility of the ions, during operation of the measuring probe, i.e. without interrupting the process.

The electrode is preferably connected to the signal-processing unit through signal connections of the shortest possible length in order to avoid a falsification of the measurement signal from capacitative disturbances and/or attenuations. As a result, the disclosed measurement method can also be applied advantageously in large industrial process plants.

Arranging the switching element between the charge source and the charge storage device further has the advantage that there are no switching elements connected directly to the signal connection. Interference from the switching elements can thereby be avoided. In addition, this makes it possible to use advantageous switching elements such as semiconductors which are characterized by low leakage currents, high switching speed and which are not prone to wear out, for example MOSFET elements.

The disclosed embodiments are based on the observation that during operation of a measuring probe, inert hydrogen-oxygen groups are formed continuously in the peripheral zones of the ion-sensitive border surfaces of the measuring probe. These hydrogen-oxygen groups are therefore no longer available as charge carriers for further measurements. Consequently, the number of freely available hydrogen-oxygen groups decreases over the course of the operating time, while the mobility of the remaining free hydrogen-oxygen groups is at the same time being curtailed to an increasing degree. Accordingly, the mobility of the charge carriers is a central parameter for the monitoring and/or the determination of the condition of an electrochemical measuring probe.

In accordance with the disclosed embodiments, the mobility of the charge carriers of an electrode is determined by measuring the discharge characteristic of a charge storage device being discharged through the electrode. As described above, the speed of this discharge is directly related to the mobility of the free charge carriers.

Accordingly, the condition, particularly the state of wear, of an electrochemical measuring probe can reliably be determined by measuring the discharge speed of an electrode.

The method and the device not only allow conclusions to be drawn on the current state of the measuring probe, but also allow more accurate predictions to be made of the future performance of the measuring probe, which leads for example to improved estimates of the life expectancy or facilitates the planning of maintenance cycles.

As a further advantage, by determining the charge carrier mobility one can also capture the dynamic behavior of a measuring probe. Thus, not only the slope and sensitivity, but also the settling time or response time of a measuring probe, depends on the mobility of the charge carriers.

The method is further particularly well suited for measuring probes that are used over long operating time periods, because the requirements in regard to non-stop operation are particularly high in this case. With the disclosed method, the improved determination of the condition of a measuring probe and the acquisition of further characteristic measurement quantities make it possible to recognize and control process parameters of the measuring probe which change only slowly and/or imperceptibly.

The electrode voltage is preferably sent by way of a signal wire to a signal-processing unit and measured at least once during the test phase. The term “signal wire” can in this case refer to all possible forms of electrically conductive connections such as copper wires, leads, connections on circuit boards or integrated circuits.

For further processing, the measurement results are for example sent to a signal-processing unit, processed directly, or put in intermediate storage. They can also be processed further at a later point in time, i.e. during normal operation of the measuring probe or in a later-following test phase. It is also possible that the further processing and/or analysis of the results takes place later for example in the signal-evaluating unit, in a transmitter or in a master computer. Finally, the long-term performance of a series of several measuring probes can be determined by means of statistical analyses in the signal-evaluating unit or in a master computer.

Under the method, the charge storage device is preferably wired in a fixed connection with the electrode, or connected to the electrode only for the duration of the verification phase. With this switchable connection, the charge storage device can be charged up in parallel with the measurement phase, and the interruption of the measurement phase can thereby be minimized. Furthermore, the charge storage device can on the one hand be connected to the charge source or, if applicable, to the supply voltage for the purpose of the charge transfer and on the other hand to the electrode for the verification phase. The charge transfer can thereby be controlled and/or timed. One can thus achieve, for example, that the flow of charge currents through the charge storage device, in particular during the test phase, is prevented.

In a possible further development of the method and the device, at least one measurement phase for the measurement of the ion concentration of a process material is arranged to take place during operation of the measuring probe. This measurement phase is interrupted during the verification phase. The measurement phase and the verification phase are thereby separated from each other, which avoids the problem that the measurement phase and the verification phase could mutually influence each other.

In a further preferred embodiment, the connector terminal of the charge storage device on the side that faces away from the electrode is electrically isolated during the test phase and/or the measurement phase. This connector terminal of the charge storage device, specifically of the capacitor, is thus free, ending in air so to speak, or if connected at all to the charge source, then only through the high open-switch resistance of the switching element. This prevents that the charge source could influence the measurements during the test phase and/or during the measurement phase.

It is advantageous if during the test phase the electrode voltage is measured a sufficient number of times to determine the characteristic parameters of the time profile of the electrode voltage during the test phase. Through these repeated measurements, it is possible to calculate more complex parameters and also to improve the accuracy of the results of the evaluation.

In a further developed version of the method, the charge of the charge storage device is removed by means of a second switching device, preferably through a ground connection. This ensures that a possibly remaining residual charge of the charge storage device cannot affect the further measurements of the ion concentration during the subsequent operation of the measuring probe. In addition, the verification phase can be terminated sooner and the normal measurement phase can be resumed immediately. This cancellation of the charge is preferably concluded before the end of the verification phase. In case the charge was depleted sufficiently during the test phase, an active removal of the residual charge can be omitted.

In a preferred version of the method, additional measurement signals such as bipolar pulses are directed to the charge storage device by means of a third switching device, preferably outside of the verification phase, i.e. typically during the measuring phase. In this way, the method can be combined with the prior-art method of error detection by means of a resistance measurement. As a coupler element, one could use the charge storage device, or also a further coupling capacitor specially dedicated to this purpose.

In the method, the verification phases can be repeated at selectively predefined time intervals, specifically in intervals of minutes, hours or days. Thus, the measurement phase is only infrequently influenced by the verification phase, and the load on the electrode from the additional charge is kept relatively small.

In an embodiment, the charge storage device can be incorporated in the measuring probe or arranged as an external charge storage device. In either arrangement, the charge storage device is arranged in parallel with the signal source and the internal resistance of the electrode.

In a further embodiment, the charge storage device can also be switched into the circuit only during the verification phase by means of a switching element. In this arrangement, the charge flow current is preferably limited by a resistor. With this concept, the charge storage device can be completely disconnected during operation of the measuring probe or during the measurement phase.

In this configuration, it is also possible for the charge source to take on the function of the charge storage device, as a particularly cost-effective solution. Furthermore, the different switching elements such as the first and the third switching element can be combined in the form of a suitable changeover switch.

As a preferred solution, the measured voltage can be sent through a signal wire of a signal-processing unit for further treatment. This treatment can consist of passing the signal on or it can involve a multitude of processing steps such as impedance conversion, amplification and/or storage. In addition, there can be further signal-processing elements incorporated in the signal-processing unit, such as a comparator element, a multiplexer unit, a processor unit, or a calculator unit.

The processing treatment of the measurement signals can be performed advantageously by means of an element serving for the analog/digital conversion. This element could also be incorporated in the signal-processing unit of the measuring probe or in an evaluating device. By digitizing the measurement values it is possible to subject them to a digital processing treatment which allows relatively complex operations to be performed and offers a simple way of storing the data in the signal-processing unit of the measuring probe, in the evaluating device, or in an external memory.

In a further developed version of the method, the measurement results can be compared to expected values for the electrode voltage, for example in the signal-processing unit of the measuring probe or in a signal-evaluating device.

The expected values for the electrode voltage can be determined through experimental and/or mathematical methods. For this purpose, it is also possible to use comparison measurements against intact measuring electrodes, i.e. other electrodes or auxiliary electrodes. As a further possibility, the expected values for the electrode voltage can also be based on maximum values, threshold values and limit values found in the regulatory literature such as national or international norm standards. Besides, the expected values can also be set by the manufacturer of the measuring probe or electrode.

The comparison between the measured and the expected values of the electrode voltage can be performed by means of a comparator device such as a comparator circuit or a computing unit. The term “computing unit” in this context is meant to include all kinds of signal-processing elements such as analog circuits, digital circuits, integrated circuits, processors, computers and the like. This comparator device can be realized preferably by means of the signal-processing unit or in a signal-evaluating unit within the evaluating unit.

The evaluating unit or the transmitter can include a variety of components such as a communication unit, a signal-evaluating unit and/or a storage unit. These units can preferably communicate bidirectionally through direct connections and exchange instructions and programs as well as measurement values and results.

In a preferred embodiment, all activities of the measuring probe and the evaluating device are coordinated by the communication unit. In addition, the communication unit can communicate bidirectionally with a master computer and transmit instructions, programs, operating data, measurement values and/or evaluated results.

A preferred embodiment further offers the capability to store operating data such as the expected values of the electrode voltage, threshold values, control parameters, characteristic numbers and programs in non-volatile memory in a storage unit in the transmitter TR. These data can for example be transmitted from a master computer to a communication unit and written into the storage unit. If needed, the data can then be read by the signal-evaluating unit.

Finally, the measuring probe can also be configured in such a way that units such as a signal-evaluating unit, a storage unit and/or a communication unit as well as an evaluating device or a transmitter with the aforementioned functional capabilities are incorporated in every measuring probe.

The disclosed device which serves to monitor and/or determine the condition of an electrochemical measuring probe, specifically a pH-measuring probe, an oxygen-measuring probe or a CO₂-measuring probe with at least one electrode and a signal-processing unit, wherein during operation of the measuring probe a process quantity associated with the ion concentration of a process material can be determined, has the distinguishing features that the measuring probe includes a charge storage device which is associated with the electrode and can be charged by way of a controllable charge transfer, that the measuring probe further includes a controller unit serving to generate a verification phase which includes a charge-up phase followed by a test phase, and that it also includes a signal wire which serves to transmit to the signal-processing unit an electrode voltage value which is measured at least once during the test phase.

The disclosed method is also suitable for determining the condition of the measuring probes that are incorporated in a process system which is cleaned from time to time by using state-of-the-art CIP or SIP processes (cleaning in place, sterilizing in place) without removing the measuring probes from the system. It is of advantage if the measurement values which are determined during such cleaning processes are taken into consideration in the overall assessment of the condition of the measuring probe.

### BRIEF DESCRIPTION OF THE DRAWINGS

Details of the disclosed method and device will become apparent from the description of the embodiments which are shown in schematic and simplified representation in the drawings, wherein:

FIG. 1 illustrates the principal structure of a system for measuring the ion concentration in a solution 6 by means of electrochemical measuring probes 1a, 1b, 1c;

FIG. 2 schematically illustrates an electrochemical measuring probe 1 which is immersed in a process material 6 and connected to an evaluating device 3;

FIG. 3 represents a block diagram of a measuring probe 1 with electrode EL, charge source Q1, charge storage device Q2 and controller unit CU, with switching elements S1, S2 and S3;

FIG. 4 represents a block diagram of a further possible embodiment with a charge storage device Q2 incorporated in the measuring probe 1;

FIG. 5 represents a block diagram of a further possible embodiment with a charge storage device Q2 that can be switched into the circuit of the measuring probe through a changeover switch S4; and

FIG. 6 schematically illustrates a time profile of the charge flow current of the charge storage device and, corresponding to this, two possible time profiles of the resultant electrode voltage and a possible choice for the timing of the measurements.

### DETAILED DESCRIPTION OF A PREFERRED EMBODIMENT

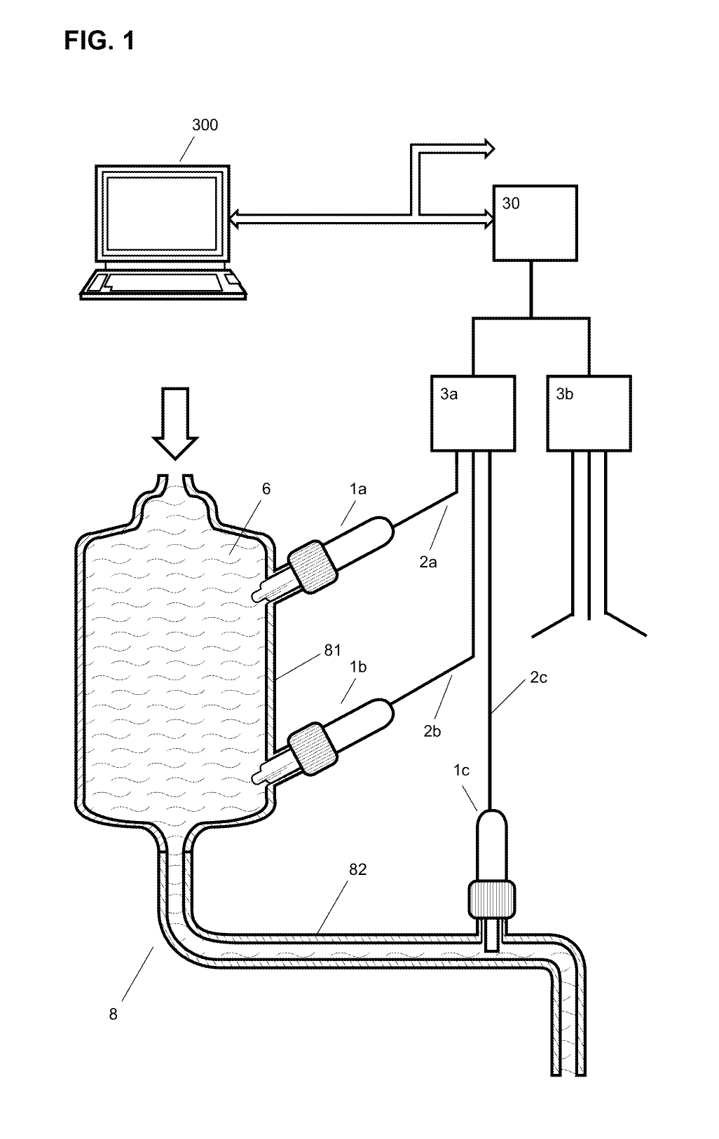

FIG. 1 illustrates a process system with a container 8 consisting of a holding vessel 81 filled with a process material 6, which may be connected by means of a connecting pipe 82 to a system unit of a next following process stage. The properties of the process material 6 are measured by means of measuring probes 1a, 1b, 1c which are connected through signal-transmitting devices 2 to an evaluating device 3a or 3b. The evaluating devices 3a, 3b which, among other functions, serve as measurement converters are connected by way of a segment coupler 30 to a master computer 300.

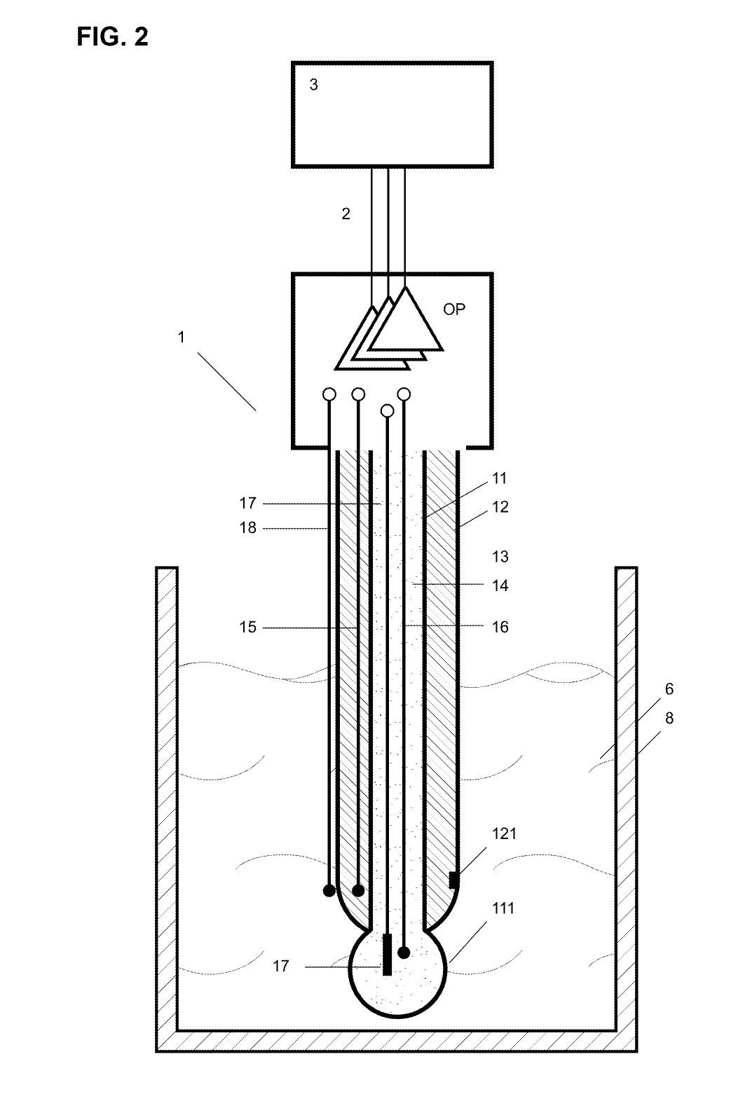

The principal design structure of an electrochemical measuring probe such as for example a pH-measuring probe, which in the configuration of a single-rod measuring chain includes a glass electrode 16, a reference electrode 15, and an auxiliary electrode 18, is represented schematically in FIG. 2. In the measuring probe 1, the glass electrode with a conductor lead element 16 and the reference electrode with a reference lead element 15 are constructively combined in one unit. Inside of a first chamber within an inner tube 11 and a thin-walled glass hemisphere or glass membrane 111 adjoining the tube, the conductor lead element 16 is immersed in a solution with a defined pH value, specifically an inner buffer 14, which establishes the electrically conductive connection between the inside of the glass membrane 111 and the conductor lead element 16. Inside of an outer tube 12, the reference lead element 15 is immersed in an electrolyte, specifically an outer buffer 13 which, by way of a porous separating wall or diaphragm 121, allows an exchange of electrical charges to take place with the measurement material 6.

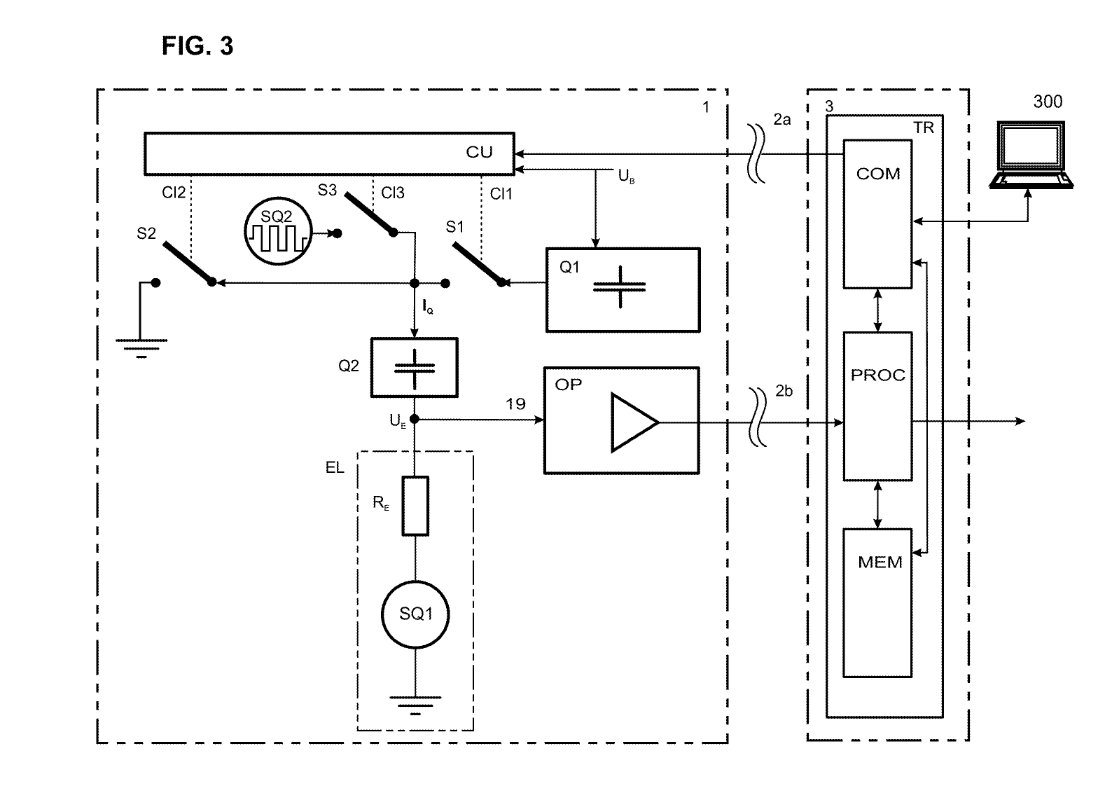

The electrical potentials of the signal source (seen as signal source SQ1 in FIG. 3) which during the measurement set themselves up at the conductor lead element 16, at the reference lead element 15, and/or at the auxiliary electrode 18 are measured and then further processed with the signal-processing unit OP, preferably an operational amplifier. In the inner buffer space, a temperature-measuring sensor 17 is arranged, which provides the possibility to automatically compensate for temperature effects and to register temperature cycles. The signal-processing unit OP, which will be described in more detail below, is incorporated in the head of the measuring probe 1 and connected by way of signal leads 2 to the evaluating device 3.

FIG. 3 shows the measuring device of FIG. 2 in an advantageous embodiment with a measuring probe 1 which includes at least one electrode EL, for example a glass electrode and a reference electrode. At the electrode EL, the voltage U_{E} establishes itself as soon as the measuring probe 1 is immersed in the process material 6. The process material 6 and the electrode EL together form a voltage source SQ1 whose internal resistance is represented in the drawing as the electrode resistance R_{E}. For example the glass membrane of a glass electrode represents a very high resistance, while the transition resistance of the reference electrode results in a relatively low resistance value.

The voltage U_{E} is sent for processing to a signal-processing unit OP by way of a signal wire 19. Next, the not yet processed, partially processed or fully processed signals are transmitted through a connecting lead 2b to a signal-evaluating unit PROC. The signal-evaluating unit PROC is incorporated in an evaluating device 3 or a transmitter 3 and can communicate through internal connections with a memory unit MEM and a communication unit COM. The processed and/or evaluated measurements can subsequently be passed on to be used for example for the control and monitoring of the process system.

The evaluating unit 3 or the transmitter TR includes a variety of components such as a communication unit COM, a signal-evaluating unit PROC, and/or a memory unit MEM, which are connected bidirectionally among each other and thus are able to exchange data, instruction or programs.

The communication unit COM coordinates all activities of the measuring probe 1 and of the evaluating device 3 and establishes the communication to the master computer 300. Through the connection 2a, instructions are transmitted from the communication unit COM to a controller unit CU in the measuring probe 1. The communication unit COM can also issue instructions to the signal-evaluating unit PROC, receive data from the signal-evaluating unit PROC, or also store data and programs in the memory unit MEM.

The controller unit CU, which can also be incorporated in the signal-processing unit OP, functions as a controller element for the switching elements S1, S2 and S3 by sending control signals through the control output terminals CL1, CL2 and CL3, thereby triggering responses in the respective switching elements. The switching elements can be configured as mechanical or electronic elements or as semiconductor elements such as transistors. However, the switching operations can also be performed directly with the controller unit CU.

For the duration of the measurement phase during which the process quantities are measured, both of the switching elements S1 and S2 are in the open state. These switching elements and the charge storage device therefore have no influence on the operating state and on the measurements of the electrodes during the measurement phase.

By means of the switching element S3, further measurement signals, such as bipolar pulses, can be delivered during the measurement phase as well as during the verification phase. These signals can be generated by way of a signal source SQ2 and coupled into the circuit through the charge storage device Q2 or also through a separate capacitor. Accordingly, after the switching element S3 has been closed, the resistance measurement method which is known from the prior art is available for the detection of functional failures.

At the start of the verification phase, the switching element S1 is closed and the switching element S2 is held in the open position, so that the charge source Q1 is connected to the charge storage device Q2. Subsequently, the charge storage device Q2 is charged up by means of a charge transfer through the charge flow current I_{Q}.

The charge transfer can be interrupted at the end of the charge-up phase by opening the switching element S1. Subsequently, the charge storage device Q2 is connected directly to the electrode EL, while being separated from the influence of the charge source Q1.

Immediately after the test phase, the remaining charge of the charge storage device Q2 can be canceled by closing the switch S2 for a suitable time period. Preferably, this will cause the charge of the charge storage device Q2 to be drained off to ground potential.

The influence that the applied charge has on the electrode EL and the electrode voltage U_{E} which establishes itself as a result can be measured, processed and passed on preferably with the aforementioned signal-processing unit OP. However, it is also possible to switch over to a further signal-processing unit (not shown in the drawing) which is provided specifically for the method.

The supply voltage for the charge source Q1 and possibly for further circuit components can be taken from the operating voltage U_{B} or tapped off parasitically from the connecting lead 2 and suitably adjusted.

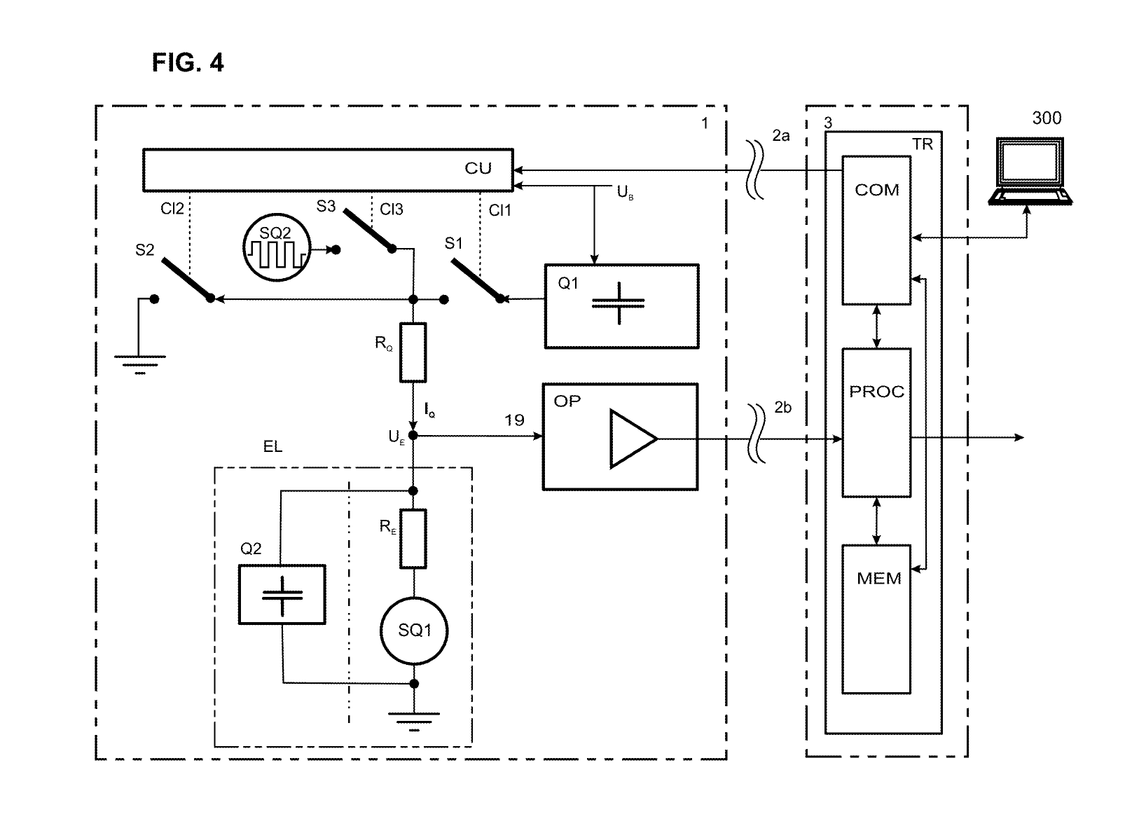

FIG. 4 illustrates a further embodiment of the device which is analogous to the embodiment of FIG. 3, except that in this case the charge storage device Q2 is arranged as an internal element inside the electrode EL or as an external element outside of the electrode and wired parallel to the signal source SQ1 and the internal resistance R_{E} of the electrode. Additionally, a resistor R_{Q} is placed in the connection between the charge storage device Q1 and the electrode EL as a means to limit the charge flow current I_{Q}. However, the resistor can also have a value of zero.

The charge flow current I_{Q} now flows during the charge-up phase through the resistor R_{Q} to the electrode EL and to the charge storage device Q2, while the electrode voltage U_{E} can still be measured on the signal wire 19. The charge storage device Q2 can be constituted in the form of a physically separate unit, or also as an inner capacitance of the electrode EL, for example as capacitance of the conductor lead elements 16 or of the reference lead elements 15.

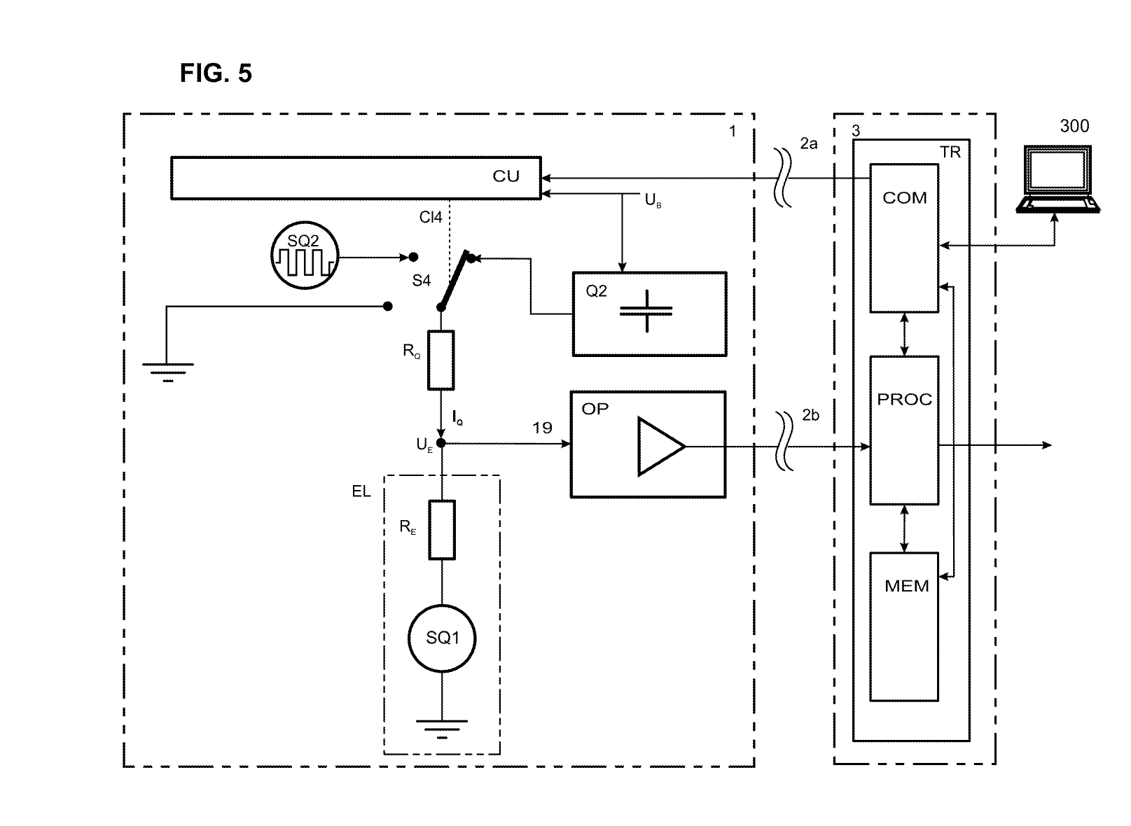

FIG. 5 represents a further embodiment of the device which is analogous to the embodiment of FIG. 3, except that in this case the charge storage device Q2 can be switched into the electrode circuit. As in FIG. 4, a resistor R_{Q}, which can also have a value of zero, is included in the connection between the charge storage device Q2 and the electrode EL as a means for limiting the charge flow current I_{Q}.

In this embodiment, the switching is realized with a changeover switch S4 which is controlled through the control output terminal CI4 of the controller unit CU. Accordingly, the switch S4 provides a selective passage for the charge voltage, the measurement signals of the signal source SQ2, or a connection to ground. However, this functional capability could also be achieved by means of individual switching elements, which would make it possible for example to connect to the measurement signals of the signal source SQ2 during the verification phase. In this example, the charge storage device Q2 is being charged directly through the operating voltage U_{B}.

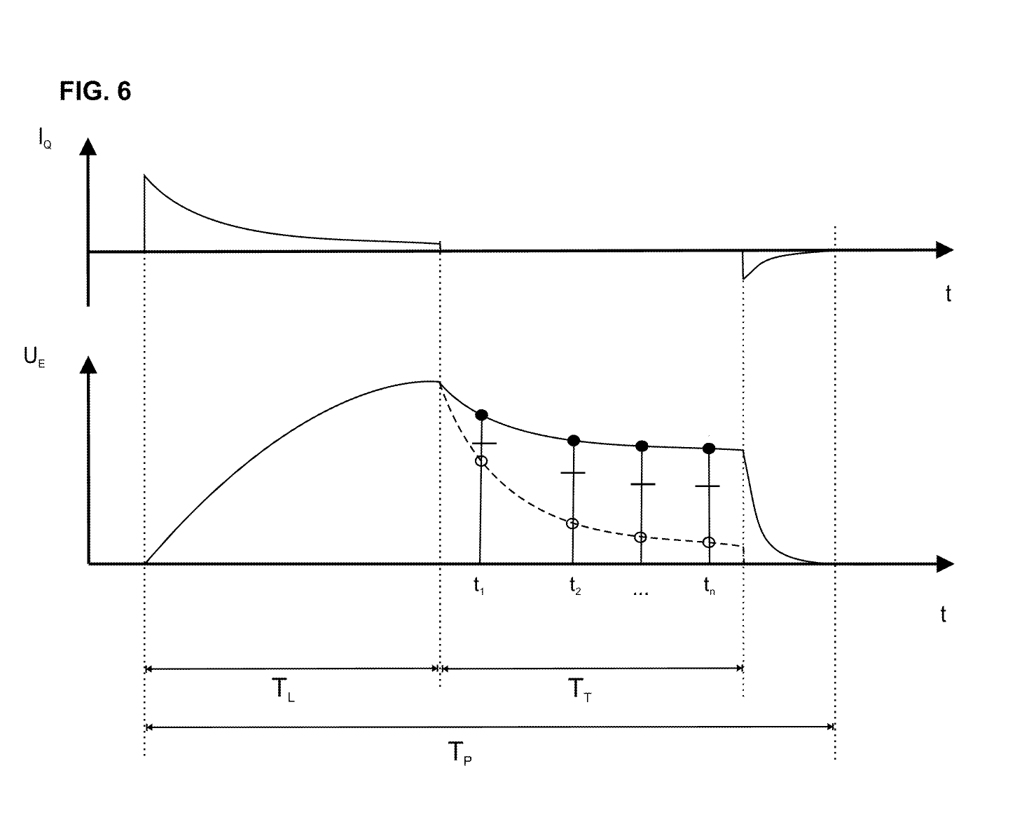

FIG. 6 shows the time profiles of the signal during a typical verification phase T_{P}. The upper graph I_{Q}(t) shows the time profile of the charge flow current I_{Q} during the charge-up phase T_{L}, the test phase T_{T}, and the discharge. The lower graph U_{E}(t) represents the time profile of the resultant electrode voltage U_{E}.

The electrode potential which exists during operation or during the measurement phase of the measuring probe 1, i.e. the potential of the signal source SQ1 across the resistance R_{E}, can take on negative values, positive values, or a value of zero, depending on the application. To simplify the situation, FIG. 6 represents the electrode voltage U_{E} for an electrode EL with a potential of zero.

Before the verification phase T_{P}, i.e. typically during operation of the measuring probe 1, a measurement is normally taken of the currently existing electrode voltage U_{E}.

By closing the switching element S1, the charge source Q1 is connected to the charge storage device Q2, whereby the start of a verification phase T_{P} and a charge-up phase T_{L} is set. Charges are being moved through this connection, which causes a rise of the charge in the charge storage device Q2, a drop of the charge flow current I_{Q}, and a corresponding rise of the electrode voltage U_{E}. The profile of the signals essentially conforms to the commonly known exponential shape.

At the end of the charge-up phase T_{L} the charge transfer is interrupted by opening the switching element S1.

Following the charge-up phase, i.e. during the test phase T_{T}, one or more measurements of the electrode voltage U_{E} can be made at the times t₁, t₂, up to and including tₙ.

The time profiles of the electrode voltage U_{E} are illustrated for two possible conditions of a measuring probe 1. Shown as examples, the slowly decreasing graph (solid line) can be the result of a used-up measuring probe 1, and the rapidly decreasing graph (broken line) can be the result of a fresh measuring probe 1.

Further, corresponding to the individual measurements, possible threshold values are shown in the form of cross bars. Based on these values, it is easy to judge the state of wear of the measuring probe 1 in this example.

In some embodiments, the test phase T_{T} can be ended by closing the second switching element S2. This canceling of the charge is preferably concluded before the end of the verification phase T_{P}. The profiles of the corresponding discharge current I_{Q} and of the electrode voltage U_{E} are shown in the final part of the verification phase T_{P}.

After the end of the verification phase T_{P}, the normal operation of the measuring probe 1, or the measurement phase of the measuring probe, can be resumed, preferably with the addition of further measurement signals such as bipolar pulses as a means of monitoring the function of the measuring probe 1.

The duration of the measurement phase is typically an hour, while the verification phase could take about five seconds. During the verification phase, the last preceding measurement value of the measurement phase could be passed along or displayed on an indicator.

The unipolar pulse can also take place after a bipolar pulse, possibly with a small time offset. It would also be conceivable to form a first signal pulse and the beginning of a second, opposite signal pulse in analogy to the known bipolar pulse and to let the end of the second signal pulse run out in accordance with the unipolar pulse.

The method disclosed herein now offers various possibilities for a precise determination of the condition of the measuring probe. The measurement values determined during the verification phase, which may consist of a part or all of the time profile of the charge storage device, are compared in the evaluating device to at least one threshold value or to characteristic profile graphs. As shown in the drawings, the evaluating unit consists of the signal-evaluating unit PROC located in the transmitter 3, or of a signal processor located in the measuring probe.

The threshold values or discharge profiles which are stored as reference data in the evaluating unit can represent possible conditions of the measuring probe, for example a quantitative measure of the reduced charge carrier mobility, a value of the response time, a value for the slope, a defective condition of the glass membrane such as a fracture of the glass, or a contamination of the measuring probe 1.

By comparing the measured discharge curve or comparing one or more points of the latter, it is therefore possible to determine one or more properties or combinations of properties that characterize the condition of the probe.

From an analysis of these data, it is also possible to establish a corresponding value for the remaining operating life or to signal a need for maintenance service.

In preferred forms of the method, at least the conditions that were found in a first and a second verification phase are registered and evaluated. For example, typical calibration parameters such as the response time, the zero point and the slope can be determined and recorded over two or more verification phases. It is also possible to record further properties of the measuring probe such as the resistance of the electrode. As a result, time profile records of the properties of the measuring probe are obtained which also have a high information content. For example the slopes of these profiles are being determined and evaluated. It is for example possible that the properties of the measuring probe for every verification phase are still within an acceptable range. Based on a rapid change in the behavior of the probe, preferably by performing an extrapolation, it can therefore be ascertained at what time a malfunction or a no longer acceptable measurement performance will have to be anticipated.

When evaluating the recorded time profiles of the properties of the measuring probe, influence factors of the measuring probe such as temperature and pH value are preferably taken into consideration, so that it can be determined whether the changes were due to factors associated with the process or to unexpected changes or problems inside the measuring probe 1.

It is particularly advantageous to use the measured test results to make adjustments to the correction factors or delay factors which are used during the measurement phase for the processing of the measurement signal. If a slope is found to be less than the value previously used, the measurement signal which may for example represent the pH value of the process material can be multiplied by a weight factor>1 in order to compensate for the change.

Thus, the disclosed method not only makes it possible to test the condition of the measuring probe, but to automatically calibrate the entire process system, without having to uninstall the measuring probes 1.

This has on the one hand the result that there will be fewer interruptions of the process and that on the other hand the performance of the system is optimized with a more precise control of the processes.

The disclosed method and device can be realized with minimal cost. The signal path for the measurement signals, specifically for a pH value measured by the measuring probe 1, and the signal path for the test signals are preferably identical.

The charge storage device can be realized for example by means of the inherent capacitances of the measurement probe or with at least one additional capacitor which is either wired in a fixed connection with the electrode EL or switched into the circuit each time a test is to be performed.

In an advantageous embodiment, a charge storage device can be charged up and switched into the circuit for the verification phase of the measuring probe 1. For example the charge storage device Q2 of FIG. 4 can be charged up during the measurement phase and switched over in the charged state to the electrode already at the start of the verification phase. The charge-up phase within the verification phase has in this case a length of zero. This means that the start of the verification phase coincides in this case with the start of the discharge of the charge storage device Q2 which is disconnected from the supply voltage Ub during this time period. In other words, a switchover takes place between the supply voltage Ub and the electrode.

What is claimed is:

1. A method for monitoring and/or for determining the condition of an electrochemical measuring probe for determining an ion concentration of a process material, the measuring probe comprising at least one electrode, the method comprising the steps of:
verifying the condition of the measuring probe at least once during the operation, the verifying step comprising the substeps of:
charging up the electrode, by one of: charging up a charge storage device belonging to the electrode with a charge transfer that is controlled by a controller, or switching to the electrode an already-charged-up charge storage device belonging to the electrode; and
testing the electrode after the charging up substep, by disconnecting the charge storage device from a charge source or a supply voltage, at the start of the testing, by measuring an electrode voltage present at the electrode at least once, and by comparing the measurement value obtained to at least one reference value.

2. The method of claim 1, wherein:
the charge storage device is wired in fixed connection with the electrode or is connected only for the duration of the charging up step, and/or the charge storage device is connected on the one hand to the charge source or to the supply voltage for the purpose of the charge transfer, and on the other hand to the electrode for the testing substep.

3. The method of claim 2, further comprising the steps of:
measuring the ion concentration of the process material at least one time during the operation of the measuring probe; and
interrupting the ion concentration measuring step during the verifying step.

4. The method of claim 3, further comprising the step of:
delivering the voltage which is present at the electrode through an amplifier to an evaluating unit, which is arranged in the measuring probe or is in a measurement converter or transmitter connected to the measuring probe.

5. The method of claim 4, wherein:
the comparing substep is achieved by comparing, in the evaluating unit, the measurement values, or, if applicable, the partial or complete time profile of the discharge of the charge storage device, to at least one threshold value or to characteristic time profile curves which are representative of possible conditions of the measuring probe.

6. The method of claim 5, further comprising the step of:
communicating a signal based upon the comparing substep, the signal indicating a corresponding value for the remaining operating life, or a need for maintenance service.

7. The method of claim 6, further comprising the steps of:
comparing to each other the respective conditions of the measuring probe determined in the verifying step at two separate times;
extrapolating, if necessary, the respective conditions to account for at least one of: the operating life of the measuring probe and the time profile of the process; and
determining, as a result of the comparing step, whether a change in the condition of the measuring probe indicates a malfunction thereof.

8. The method of claim 5, further comprising the step of:
adjusting at least one correction factor or delay factor used during the measurement phase to process a measurement signal from the measurement probe, based upon the determined condition of the measuring probe.

9. The method of claim 1, further comprising the steps of:
measuring the electrode voltage a number of times during the test phase; and
determining the characteristic parameters of the time profile of the electrode voltage therefrom.

10. The method of claim 1, further comprising the step of:
cancelling the charge of the charge storage device after the test phase.

11. The method of claim 1, further comprising the step of:
directing further measurement signals, such as bipolar pulses, to the electrode during the measurement phase to perform additional resistance measurements on the electrode.

12. The method of claim 1, further comprising the step of:
repeating the verifying step at a predefined, but changeable, time interval.

13. An electrochemical measuring probe for use in contact with a process material, comprising:
an electrode;
a signal-processing unit which determines a measurement quantity related to an ion concentration of the process material during operation of the measuring probe;
a charge storage device belonging to the electrode, the charge stored therein received from a charge source or a supply voltage through a controllable charge transfer;
a controller unit to generate a verification phase that which includes a charge phase followed by a test phase,
a switching device for disconnecting the charge storage device from the charge source or the supply voltage at the start of the test phase, and
a signal wire for transmitting an electrode voltage value measured at least once during the test phase to the signal-processing unit.

14. The measurement probe of claim 13, further comprising:
a first switching device that connects the charge storage device to the charge source.

15. The measurement probe of claim 14, further comprising:
a second switching device through which the charge in the charge storage device is selectively drained.

16. The device of claim 15, wherein:
the second switching device drains the charge to a ground connection.

17. The measurement probe of claim 15, further comprising:
a third switching device for directing to the electrode further measurement signals for measuring the resistance of the electrode.

18. The measurement probe of claim 13, wherein:
a connector terminal of the charge storage device, which faces away from the electrode, is electrically isolated during at least one of the test phase and the measurement phase.

19. The measurement probe of claim 13, wherein:
the measuring probe is selected from the group consisting of: a pH-measuring probe, an oxygen-measuring probe and a CO₂-measuring probe.
